(19) United States
(12) Patent Application Publication
(10) Pub. No.: US 2026/0052918 A1
(43) Pub. Date: Feb. 19, 2026

(54) SELECTIVE ETCHING OF SILICON-AND-GERMANIUM-CONTAINING MATERIAL

(71) Applicant: Applied Materials, Inc., Santa Clara, CA (US)

(72) Inventors: Bo Wang, San Jose, CA (US); Baiwei Wang, Santa Clara, CA (US); Xiaolin C. Chen, San Ramon, CA (US); Wanxing Xu, Sunnyvale, CA (US); Zhenjiang Cui, San Jose, CA (US); Anchuan Wang, San Jose, CA (US)

(73) Assignee: Applied Materials, Inc., Santa Clara, CA (US)

(21) Appl. No.: 18/805,783

(22) Filed: Aug. 15, 2024

(51) Int. Cl. H01L 21/3065

(52) U.S. Cl. CPC H01L 21/3065

(57) ABSTRACT

Exemplary semiconductor processing methods may include providing a fluorine-containing precursor and a secondary precursor to a processing region of a semiconductor processing chamber. The secondary precursor may be or include a carbon-containing precursor, a hydrogen-containing precursor, a nitrogen-containing precursor, or an oxygen-containing precursor. A substrate may be housed within the processing region. A silicon-containing material and a silicon-and-germanium-containing material may be disposed on the substrate. The methods may include contacting the substrate with the fluorine-containing precursor and the secondary precursor. The methods may include selectively removing at least a portion of the silicon-and-germanium-containing material from the substrate. The processing region may be maintained at a temperature of greater than or about 200° C.

### TECHNICAL FIELD

The present technology relates to semiconductor processes and equipment. More specifically, the present technology relates to selectively etching materials relative to other materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes one material over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a fluorine-containing precursor and a secondary precursor to a processing region of a semiconductor processing chamber. The secondary precursor may be or include a carbon-containing precursor, a hydrogen-containing precursor, a nitrogen-containing precursor, or an oxygen-containing precursor. A substrate may be housed within the processing region. A silicon-containing material and a silicon-and-germanium-containing material may be disposed on the substrate. The methods may include contacting the substrate with the fluorine-containing precursor and the secondary precursor. The methods may include selectively removing at least a portion of the silicon-and-germanium-containing material from the substrate. The processing region may be maintained at a temperature of greater than or about 200° C.

In some embodiments, the fluorine-containing precursor may be or include nitrogen trifluoride (NF₃), sulfur tetrafluoride (SF₄), sulfur hexafluoride (SF₆), carbon tetrafluoride (CF₄), or tungsten hexafluoride (WF₆). The secondary gas may be the carbon-containing precursor. The carbon containing precursor may be or include methane (CH₄). The secondary gas may be the hydrogen-containing precursor. The hydrogen containing precursor may be or include diatomic hydrogen (H₂) or ammonia (NH₃). A flow rate ratio of the fluorine-containing precursor relative to the hydrogen-containing precursor may be greater than or about 10:1. The secondary gas may be the nitrogen-containing precursor. The nitrogen containing precursor may be or include ammonia (NH₃). The secondary gas may be the oxygen-containing precursor. The oxygen containing precursor may be or include diatomic oxygen (O₂). The processing region may be maintained plasma-free. The processing region may be maintained at a pressure of greater than or about 1 Torr. An etch rate of the silicon-and-germanium-containing material may be greater than or about 0.5 Å/minute.

Some embodiments of the present technology may encompass semiconductor processing methods. The methods may include providing a fluorine-containing precursor, an oxygen-containing precursor, and a hydrogen-containing precursor to a processing region of a semiconductor processing chamber. A substrate may be housed within the processing region. A silicon-containing material and a silicon-and-germanium-containing material may be disposed on the substrate. The methods may include contacting the substrate with the fluorine-containing precursor, the oxygen-containing precursor, and the hydrogen-containing precursor. The methods may include selectively removing at least a portion of the silicon-and-germanium-containing material from the substrate. The processing region may be maintained at a temperature of greater than or about 200° C.

In some embodiments, the fluorine-containing precursor may be or include tungsten hexafluoride (WF₆). The oxygen-containing precursor may be or include diatomic oxygen (O₂). The hydrogen-containing precursor may be or include diatomic hydrogen (H₂). The processing region may be maintained plasma-free. The processing region may be maintained at a temperature of greater than or about 400° C. The processing region may be maintained at a pressure of greater than or about 3 Torr.

Some embodiments of the present technology may encompass semiconductor processing methods. The methods may include providing a halogen-containing precursor and one or more secondary precursors to a processing region of a semiconductor processing chamber. The secondary precursors may include a carbon-containing precursor, a hydrogen-containing precursor, a nitrogen-containing precursor, or an oxygen-containing precursor. A substrate may be housed within the processing region. A silicon-containing material and a silicon-and-germanium-containing material may be disposed on the substrate. The methods may include contacting the substrate with the halogen-containing precursor and the secondary precursor. The methods may include selectively removing at least a portion of the silicon-and-germanium-containing material from the substrate. The processing region may be maintained plasma-free.

In some embodiments, the halogen-containing precursor may be or include nitrogen trifluoride (NF₃), sulfur tetrafluoride (SF₄), sulfur hexafluoride (SF₆), carbon tetrafluoride (CF₄), or tungsten hexafluoride (WF₆). The processing region may be maintained at a temperature of greater than or about 350° C.

Such technology may provide numerous benefits over conventional systems and techniques. For example, the processes may selectively etch silicon-and-germanium-containing material within semiconductor structures. Additionally, the processes may uniformly etch silicon-and-germanium-containing without forming residue. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

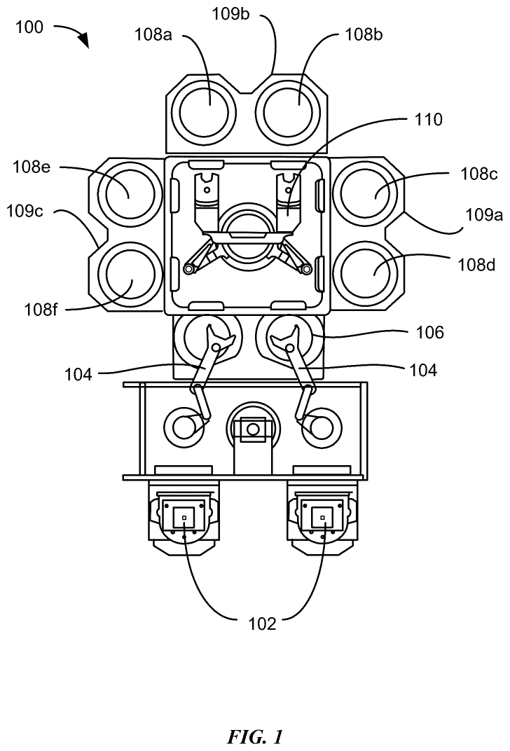

FIG. 1 shows a top plan view of one embodiment of an exemplary processing system according to some embodiments of the present technology.

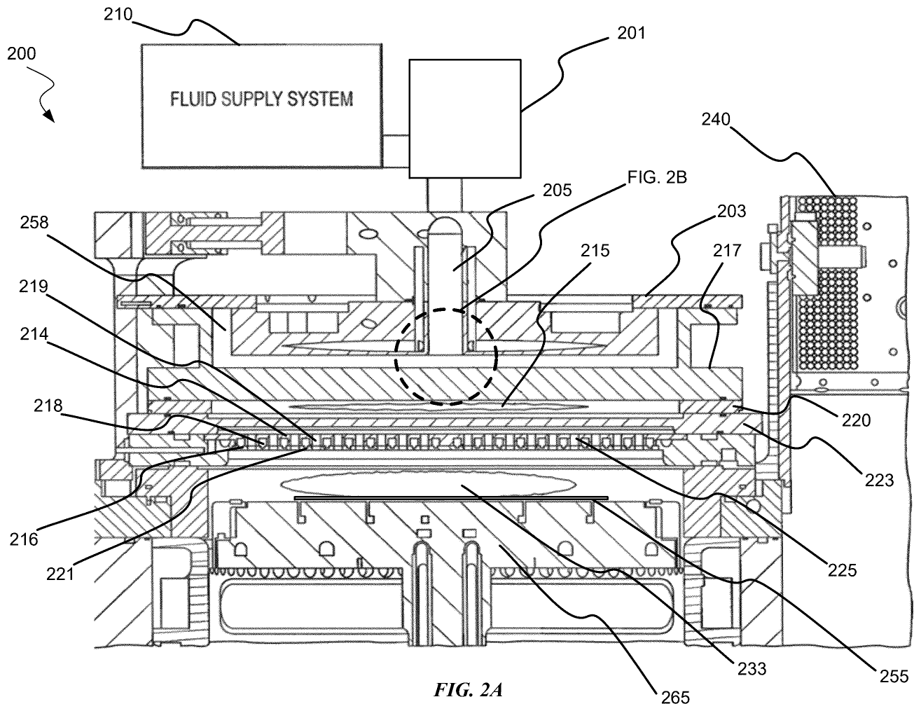

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

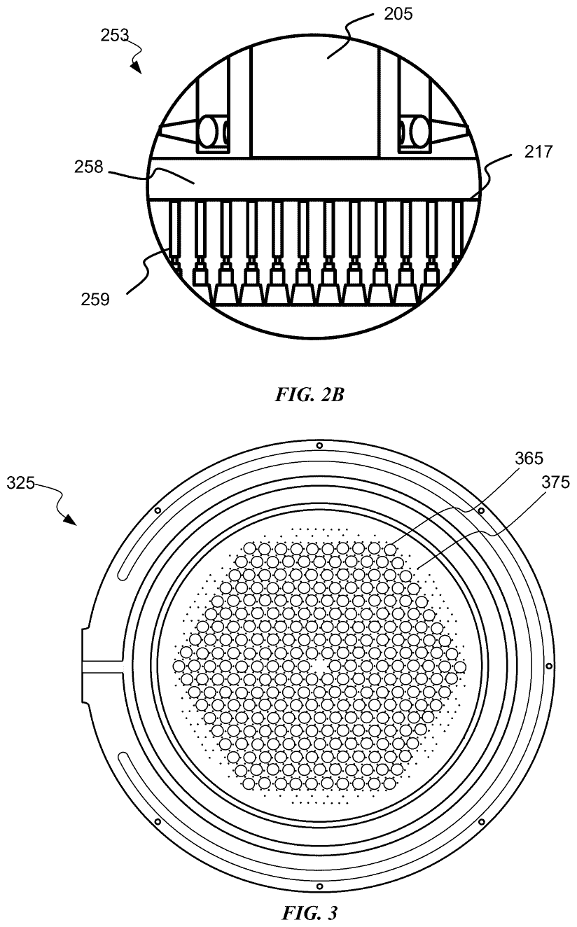

FIG. 3 shows a bottom plan view of an exemplary showerhead according to some embodiments of the present technology.

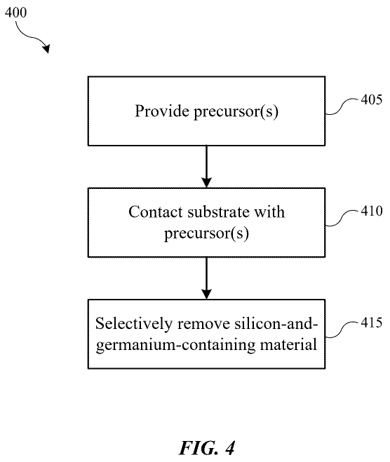

FIG. 4 shows exemplary operations in a method according to some embodiments of the present technology.

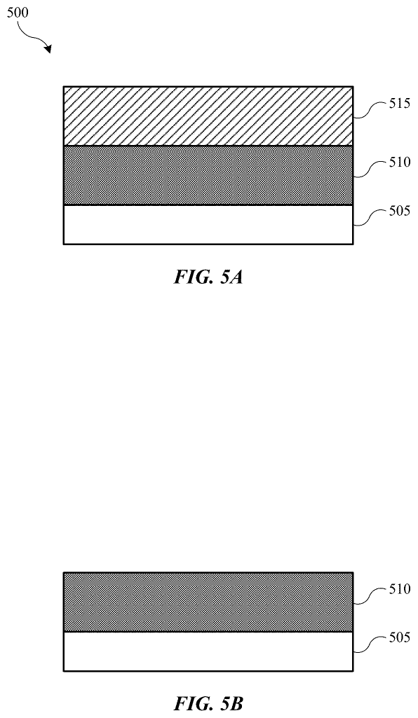

FIGS. 5A-5B show cross-sectional views of substrates being processed according to some embodiments of the present technology.

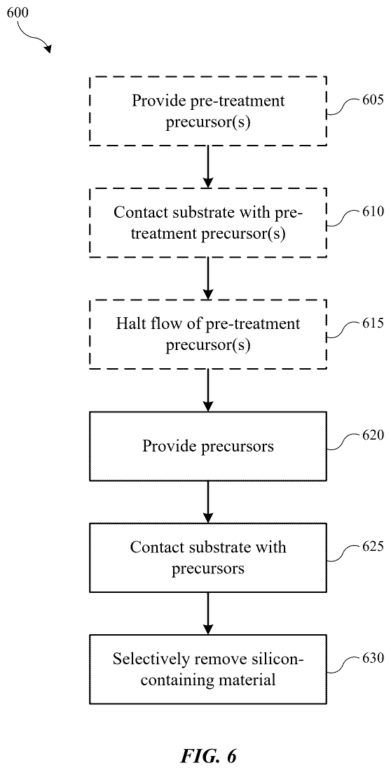

FIG. 6 shows exemplary operations in a method according to some embodiments of the present technology.

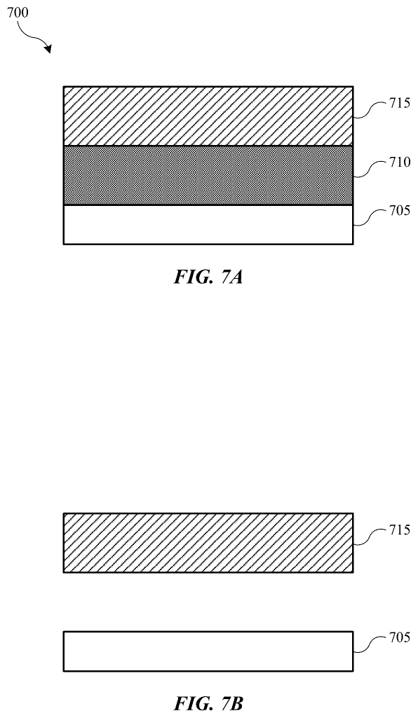

FIGS. 7A-7B show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D devices to 3D devices, many process operations are modified from vertical to horizontal operations. Additionally, as 3D structures grow, the aspect ratios of features, such as layers of material, and other structures increase, sometimes dramatically. During 3D device processing, stacked layers of materials may be formed on a substrate. Some of the layers may be recessed or removed relative to other layers. However, as the aspect ratios of materials continue to increase, etchants may have difficulties in effectively etching the materials that are desired to be recessed or removed. This may result in non-uniform etching of materials.

Many conventional technologies utilize halogen-containing precursors to selectively etch one material relative to another material. However, many conventional technologies operate at reduced temperatures and may form plasma effluents. However, these conventional technologies may suffer from reduced selectivity and/or the formation of residues. The use of plasma effluents may damage structures or materials disposed on the substrate being processed. Additionally, conventional technologies may suffer from less than desirable etch profiles, which may be due to the processing conditions and/or reduced selectivity.

The present technology overcomes these issues, as well as other issues associated with other applications, by performing a dry etch process which may selectively etch silicon-and-germanium-containing material, while limiting etching of silicon-containing material. By utilizing particular precursor combinations, including the use of a halogen-containing precursor and one or more secondary precursors, at higher temperatures, exposed surfaces of the silicon-and-germanium-containing material may be etched uniformly and without the formation of residue. In this way, the present technology may address selectivity issues associated with conventional etching technologies.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

FIG. 2A shows a cross-sectional view of an exemplary process chamber system 200 with partitioned plasma generation regions within the processing chamber, and which may be configured to perform processes as described further below. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system 201 may optionally be included in the system, and may process a first gas which then travels through gas inlet assembly 205. The inlet assembly 205 may include two or more distinct gas supply channels where the second channel may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems, such as microwave plasma-generating systems.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter etch selectivity, e.g., SiGex:Si etch ratios, SiGex:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

The chambers discussed previously may be used in performing exemplary methods including etching methods. Turning to FIG. 4, exemplary operations in a method 400 according to embodiments of the present technology are illustrated. Prior to the first operation of the method a substrate may be processed in one or more ways before being placed within a processing region of a chamber in which method 400 may be performed. For example, one or more materials may be formed on the substrate. The one or more materials may include any number of materials, and may include a silicon-containing material and a silicon-and-germanium-containing material, amongst other materials. In embodiments, the silicon-containing material may be silicon, such as polysilicon. The silicon-and-germanium-containing material may be silicon germanium. Although the remaining disclosure will discuss silicon-containing material and silicon-and-germanium-containing material, other known materials may be substituted for one or more of the materials. Some or all of these operations may be performed in chambers or system tools as previously described, or may be performed in different chambers on the same system tool, which may include the chamber in which the operations of method 400 are performed.

Method 400 may include providing one or more precursors to a processing region of a semiconductor processing chamber to selectively and uniformly etch silicon-and-germanium-containing material. An exemplary semiconductor processing chamber may be chamber 200 previously described. The one or more precursors may include one or more halogen-containing precursors, an oxygen-containing precursor, and/or one or more secondary precursors. Carrier gases or inert gases may also be provided with the halogen-containing precursor and one or more secondary precursors. The carrier gases, which may be inert gases, such as argon (Ar), helium (He), or other inert gases, may be provided to help control uniformity, particle distribution, and/or pressure.

The halogen-containing precursor provided at operation 405 may be, for example, a fluorine-containing precursor although other halogen-containing precursors are contemplated. Exemplary fluorine-containing precursors may be or include, but are not limited to, atomic fluorine (F), diatomic fluorine (F₂), nitrogen trifluoride (NF₃), sulfur tetrafluoride (SF₄), sulfur hexafluoride (SF₆), carbon tetrafluoride (CF₄), tungsten hexafluoride (WF₆), xenon difluoride (XeF₂), as well as various other fluorine-containing precursors used or useful in semiconductor processing.

Exemplary oxygen-containing precursors may be or include, but are not limited to, atomic oxygen (O), diatomic oxygen (O₂), ozone (O₃), nitrous oxide (N₂O), nitrogen dioxide (NO₂), hydrogen peroxide (H₂O₂), as well as various other oxygen-containing precursors used or useful in semiconductor processing.

The secondary precursor may be or include, but is not limited to, a carbon-containing precursor, a hydrogen-containing precursor, a nitrogen-containing precursor, or an oxygen-containing precursor. Exemplary carbon-containing precursors may be or include, but are not limited to, hydrocarbons, such as methane (CH₄), acetylene (C₂H₂), ethane (C₂H₆), as well as various other carbon-containing precursors used or useful in semiconductor processing. Exemplary hydrogen-containing precursors may be or include, but are not limited to, hydrocarbons, such as diatomic hydrogen (H₂), ammonia (NH₃), water or steam (H₂O), diimide (N₂H₂), hydrazine (N₂H₄), as well as various other hydrogen-containing precursors used or useful in semiconductor processing. Exemplary nitrogen-containing precursors may be or include, but are not limited to, hydrocarbons, such as diatomic nitrogen (N₂), NH₃, N₂O, NO₂, N₂H₂, N₂H₄, as well as various other nitrogen-containing precursors used or useful in semiconductor processing. When the secondary precursor is or includes oxygen, exemplary oxygen-containing precursors may be or include any of the previously discussed oxygen-containing precursor, as well as various other oxygen-containing precursors used or useful in semiconductor processing.

Flow rates of the halogen-containing precursor, the oxygen-containing precursor, and the one or more secondary precursors may be any flow rate. At higher flow rates of the halogen-containing precursor, an etch rate may increase. As such, the flow rate of the halogen-containing precursor may be greater than or about 10 sccm, and may be greater than or about 20 sccm, greater than or about 30 sccm, greater than or about 40 sccm, greater than or about 50 sccm, greater than or about 100 sccm, greater than or about 250 sccm, greater than or about 500 sccm, greater than or about 750 sccm, greater than or about 1,000 sccm, or more. Conversely, to maintain control of an amount of material removed during the etch, the flow rate of the halogen-containing precursor may be less than or about 1.00 sccm, and may be less than or about 750 sccm, less than or about 500 sccm, less than or about 250 sccm, less than or about 100 sccm, less than or about 50 sccm, less than or about 40 sccm, less than or about 30 sccm, less than or about 20 sccm, less than or about 10 sccm, or less.

In embodiments where the secondary precursor is a hydrogen-containing precursor, to selectively etch the silicon-and-germanium-containing material, a flow rate ratio of the halogen-containing precursor relative to the hydrogen-containing precursor may be greater than or about 10:1, and may be greater than or about 12:1, greater than or about 14:1, greater than or about 15:1, greater than or about 16:1, greater than or about 17:1, greater than or about 18:1, greater than or about 19:1, greater than or about 20:1, greater than or about 22:1, greater than or about 24:1, greater than or about 25:1, or more. At reduced flow rate ratios, the process may pivot to selectively etching silicon-containing material rather than selectively etching silicon-and-germanium-containing material.

In embodiments where the precursors include a halogen-containing precursor, such as WF₆, and an oxygen-containing precursor, such as O₂, a flow rate ratio of the halogen-containing precursor, such as WF₆, relative to the oxygen-containing precursor, such as O₂, may be between about 10:1 and about 1:10, such as between about 9:1 and about 1:9, between about 8:1 and about 1:8, between about 7:1 and about 1:7, between about 6:1 and about 1:6, between about 5:1 and about 1:5, or between any of the previously stated values. Similarly, a flow rate ratio a flow rate ratio of the halogen-containing precursor, such as WF₆, and the oxygen-containing precursor, such as O₂, relative to the secondary precursor, such as NH₃, may be between about 20:1 and about 1:20, such as between about 18:1 and about 1:18, between about 16:1 and about 1:16, between about 14:1 and about 1:14, between about 12:1 and about 1:12, between about 10:1 and about 1:10, or between any of the previously stated values. At higher flow rate ratios of the halogen-containing precursor, such as WF₆, and the oxygen-containing precursor, such as O₂, relative to the secondary precursor, such as NH₃, similar to the flow rate ratio of the halogen-containing precursor relative to the hydrogen-containing precursor, silicon-containing material may begin to etch at an increased rate, thereby reducing the selectivity of the etch of silicon-and-germanium-containing material. At reduced flow rate ratios of the halogen-containing precursor, such as WF₆, and the oxygen-containing precursor, such as O₂, relative to the secondary precursor, such as NH₃, the etch rate of silicon-and-germanium-containing material may drastically reduce. Additionally, when the halogen-containing precursor is or includes WF₆, increased deposition of tungsten (W) may occur.

In embodiments, method 400 may be a thermal process. That is, the processing region may be maintained plasma-free during the entirety of method 400. In such embodiments, method 400 may not include remote plasma formation and may not include providing plasma power to the processing region. By performing a thermal or plasma-free process, damage to the structure being etched may be reduced. Additionally, better control of the etch may result and provide a better etch profile. However, it is contemplated that some embodiments may include forming plasma effluents of one or more precursors. For example, some or all of the precursors may be provided to a remote plasma system, such as remote plasma system 201. Remote plasma effluents may be formed of some or all of the precursors then provided to the processing region. The remote plasma effluents may be capacitively coupled plasma (CCP) effluents or may be inductively coupled plasma (ICP) effluents. In other embodiments, a local plasma may be formed directly in the processing region.

At operation 410, method 400 may include contacting the substrate with the precursors, such as the halogen-containing precursor, the oxygen-containing precursor, and/or the one or more secondary precursors. During the contacting at operation 410, the halogen-containing precursor, which may include fluorine, may thermally react with or may produce halogen radicals to react with both silicon and germanium in the silicon-and-germanium-containing material. The halogen-containing precursor or halogen radicals, if formed, may preferentially react with germanium due to the weaker bond and, thus, the silicon-and-germanium-containing material may be etched selectively over the silicon-containing material. When the precursors include WF₆ and O₂, for example, the WF₆ and O₂ may react to produce F₂. F₂ may also preferentially react with germanium due to the weaker bond and, thus, the silicon-and-germanium-containing material may be etched selectively over the silicon-containing material. By including the secondary precursors, oxidation of the silicon-and-germanium-containing material may be reduced and/or prevented. If the silicon-and-germanium-containing material were to oxidize, the etch rate of silicon-and-germanium-containing material would reduce and may reduce to a point in which the silicon-containing material is etched at a faster rate than the silicon-and-germanium-containing material.

Method 400 may include selectively removing at least a portion of the silicon-and-germanium-containing material from the substrate at operation 415. In embodiments, method 400 may remove silicon-and-germanium-containing material without the formation of residue. That is, method 400 may be residue-free. By performing the operations previously discussed, silicon-and-germanium-containing material may be removed relative to silicon-containing material at a selectivity of greater than or about 1:1, and removed at a selectivity of greater than or about 1.1:1, greater than or about 1.2:1, greater than or about 1.3:1, greater than or about 1.4:1, greater than or about 1.5:1, greater than or about 1.6:1, greater than or about 1.7:1, greater than or about 1.8:1, greater than or about 1.9:1, greater than or about 2:1, or more.

While method 400 may selectively remove silicon-and-germanium-containing material relative to silicon-containing material, it is also contemplated that method 400 may remove silicon-and-germanium-containing material relative to silicon-and-oxygen-containing material, such as silicon oxide, silicon-nitrogen-containing material, such as silicon nitride, and various high dielectric constant materials.

An etch rate of the silicon-and-germanium-containing material may be greater than or about 0.5 Å/minute, and may be greater than or about 0.6 Å/minute, greater than or about 0.7 Å/minute, greater than or about 0.75 Å/minute, greater than or about 0.8 Å/minute, greater than or about 0.85 Å/minute, greater than or about 0.9 Å/minute, greater than or about 0.95 Å/minute, greater than or about 1.0 Å/minute, greater than or about 1.05 Å/minute, greater than or about 1.0 Å/minute, greater than or about 1.05 Å/minute, greater than or about 1.1 Å/minute, greater than or about 1.15 Å/minute, greater than or about 1.2 Å/minute, greater than or about 1.25 Å/minute, or more.

Turning to FIGS. 5A-5B, cross-sectional views of structure 500 being processed according to some embodiments of the present technology are illustrated. As illustrated in FIG. 5A substrate 505 may have a plurality of stacked layers overlying the substrate, which may include a layer of a silicon-containing material 510 and a layer of a silicon-and-germanium-containing material 515. As previously discussed, the layer of the silicon-containing material 510 may be, for example, polysilicon and the layer of the silicon-and-germanium-containing material 510 may be, for example, silicon germanium. Although illustrated with only two layers of material, exemplary structures may include any number of layers, and it is to be understood that the figures are only schematics to illustrate aspects of the present technology.

FIG. 5B illustrates the structure after methods according to the present technology have begun to be performed, such as discussed with respect to FIG. 4 above. Precursors or, if formed, plasma effluents may interact with the substrate 505 and exposed materials. As described above, at least a portion of the silicon-and-germanium-containing material 515 may be selectively removed relative to the silicon-containing material 510. By utilizing precursors and processing as discussed throughout the present technology, the silicon-and-germanium-containing material may be etched from the substrate 505.

Turning to FIG. 6, exemplary operations in a method 600 according to embodiments of the present technology are illustrated. Prior to the first operation of the method, a substrate may be processed in one or more ways before being placed within a processing region of a chamber in which method 600 may be performed. For example, one or more materials may be formed on the substrate. The one or more materials may include any number of materials, and may include a silicon-containing material and a silicon-and-germanium-containing material, amongst other materials. In embodiments, the silicon-containing material may be silicon, such as polysilicon. The silicon-and-germanium-containing material may be silicon germanium. Although the remaining disclosure will discuss silicon-containing material and silicon-and-germanium-containing material, other known materials may be substituted for one or more of the materials. Some or all of these operations may be performed in chambers or system tools as previously described, or may be performed in different chambers on the same system tool, which may include the chamber in which the operations of method 400 are performed.

Method 600 may include providing one or more precursors to a processing region of a semiconductor processing chamber to selectively and uniformly etch silicon-containing material. An exemplary semiconductor processing chamber may be chamber 200 previously described. Prior to performing the main etch, method 600 may include performing an optional pre-treatment. The optional pre-treatment may include providing one or more pre-treatment precursors to the processing region at optional operation 605 and contacting the structure or substrate with the one or more pre-treatment precursors at optional operation 610.

The one or more pre-treatment precursors may include a boron-containing precursor, such as a boron-and-halogen-containing precursor. Exemplary pre-treatment precursors may be or include, but are not limited to, boron trichloride (BCl₃), boron trifluoride (BF₃), boron tribromide (BBr₃), or boron triiodide (BI₃), as well as various other boron-containing precursors or boron-and-halogen-containing precursors used or useful in semiconductor processing. Carrier gases or inert gases may also be provided with the boron-containing precursor and one or more secondary precursors. The carrier gases, which may be inert gases, such as argon (Ar), helium (He), or other inert gases, may be provided to help control uniformity, particle distribution, and/or pressure.

Contacting the structure or substrate with the one or more pre-treatment precursors at optional operation 610 may dope the silicon-and-germanium-containing with boron. Since boron is an electron acceptor and germanium is an electron donor, when compared to silicon, the pre-treatment precursors may selectively dope the silicon-and-germanium-containing material with boron. When doped with boron, the silicon-and-germanium-containing material is doped with boron, the silicon-and-germanium-containing material may be resistant to halogen-containing precursors, such as fluorine-containing precursors that may be used to selectively etch the silicon-containing material. Therefore, the boron doping of the silicon-and-germanium-containing material may result in method 600 being a selective etch of silicon-containing material relative to silicon-and-germanium-containing material.

At optional operation 615, method 600 may include halting a flow of the one or more pre-treatment precursors. After the flow of the one or more pre-treatment precursors is halted, the processing region may be purged. Alternatively, the substrate may be moved from a first semiconductor processing chamber, in which the pre-treatment is performed, to a second semiconductor processing chamber, in which the main etch may be performed.

At operation 620, method 600 may include providing one or more precursors to the processing region of the semiconductor processing chamber. The one or more precursors may include one or more halogen-containing precursors, an oxygen-containing precursor, and/or one or more secondary precursors. Carrier gases or inert gases may also be provided with the halogen-containing precursor and one or more secondary precursors. The carrier gases, which may be inert gases, such as argon (Ar), helium (He), or other inert gases, may be provided to help control uniformity, particle distribution, and/or pressure.

The halogen-containing precursor provided at operation 405 may be, for example, a fluorine-containing precursor although other halogen-containing precursors, such as a chlorine-containing precursor, are contemplated. Exemplary fluorine-containing precursors may be any precursor previously discussed with regard to method 400. Additional halogen-containing precursors may also include any of the previously discussed pre-treatment precursors. Exemplary oxygen-containing precursors may be any precursor previously discussed with regard to method 400. Exemplary secondary precursors may be any precursor previously discussed with regard to method 400.

Flow rates of the halogen-containing precursor, the oxygen-containing precursor, and the one or more secondary precursors may be any flow rate. At higher flow rates of the halogen-containing precursor, an etch rate may increase. As such, the flow rate of the halogen-containing precursor may be greater than or about 10 sccm, and may be greater than or about 20 sccm, greater than or about 30 sccm, greater than or about 40 sccm, greater than or about 50 sccm, greater than or about 100 sccm, greater than or about 250 sccm, greater than or about 500 sccm, greater than or about 750 sccm, greater than or about 1,000 sccm, or more. Conversely, to maintain control of an amount of material removed during the etch, the flow rate of the halogen-containing precursor may be less than or about 1.00 sccm, and may be less than or about 750 sccm, less than or about 500 sccm, less than or about 250 sccm, less than or about 100 sccm, less than or about 50 sccm, less than or about 40 sccm, less than or about 30 sccm, less than or about 20 sccm, less than or about 10 sccm, or less.

In embodiments where the secondary precursor is a hydrogen-containing precursor, to selectively etch the silicon-and-germanium-containing material, a flow rate ratio of the halogen-containing precursor relative to the hydrogen-containing precursor may be less than or about 25:1, and may be less than or about 24:1, less than or about 23:1, less than or about 22:1, less than or about 21:1, less than or about 20:1, less than or about 19:1, less than or about 18:1, less than or about 17:1, less than or about 16:1, less than or about 15:1, less than or about 14:1, less than or about 13:1, less than or about 12:1, less than or about 11:1, less than or about 10:1, or less. At increased flow rate ratios, the process may pivot to selectively etching silicon-and-germanium-containing material rather than selectively etching silicon-containing material.

In embodiments where the precursors provided at operation 620 include a halogen-containing precursor and a boron-containing precursor, a flow rate ratio of the of the halogen-containing precursor relative to the boron-containing precursor may be between about 50:1 and about 1:50, such as between about 40:1 and about 1:40, between about 30:1 and about 1:30, between about 20:1 and about 1:20, between about 18:1 and about 1:18, between about 16:1 and about 1:16, between about 14:1 and about 1:14, between about 12:1 and about 1:12, between about 10:1 and about 1:10, or between any of the previously stated values.

In embodiments where the precursors include a halogen-containing precursor, such as WF₆, and an oxygen-containing precursor, such as O₂, a flow rate ratio of the halogen-containing precursor, such as WF₆, relative to the oxygen-containing precursor, such as O₂, may be between about 10:1 and about 1:10, such as between about 9:1 and about 1:9, between about 8:1 and about 1:8, between about 7:1 and about 1:7, between about 6:1 and about 1:6, or between about 5:1 and about 1:5. Similarly, a flow rate ratio a flow rate ratio of the halogen-containing precursor, such as WF₆, and the oxygen-containing precursor, such as O₂, relative to the secondary precursor, such as NH₃, may be between about 50:1 and about 1:50, such as between about 40:1 and about 1:40, between about 30:1 and about 1:30, between about 20:1 and about 1:20, between about 18:1 and about 1:18, between about 16:1 and about 1:16, between about 14:1 and about 1:14, between about 12:1 and about 1:12, between about 10:1 and about 1:10, or between any of the previously stated values. At higher flow rate ratios of the halogen-containing precursor, such as WF₆, and the oxygen-containing precursor, such as O₂, relative to the secondary precursor, such as NH₃, silicon-containing material may begin to etch at an increased rate. At reduced flow rate ratios of the halogen-containing precursor, such as WF₆, and the oxygen-containing precursor, such as O₂, relative to the secondary precursor, such as NH₃, the etch rate of silicon-containing material may drastically reduce. Additionally, when the halogen-containing precursor is or includes WF₆, increased deposition of tungsten (W) may occur.

In embodiments, method 600 may be a thermal process. That is, the processing region may be maintained plasma-free during the entirety of method 600. In such embodiments, method 600 may not include remote plasma formation and may not include providing plasma power to the processing region. By performing a thermal or plasma-free process, damage to the structure being etched may be reduced. Additionally, better control of the etch may result and provide a better etch profile. However, it is contemplated that some embodiments may include forming plasma effluents of one or more precursors. For example, some or all of the precursors may be provided to a remote plasma system, such as remote plasma system 201. Remote plasma effluents may be formed of some or all of the precursors then provided to the processing region. The remote plasma effluents may be CCP effluents or may be ICP effluents. In other embodiments, a local plasma may be formed directly in the processing region.

At operation 625, method 600 may include contacting the substrate with the precursors, such as the halogen-containing precursor, the oxygen-containing precursor, and/or the one or more secondary precursors. During the contacting at operation 410, the halogen-containing precursor, which may include fluorine, may thermally react with or may produce halogen radicals that may react with both silicon-containing material and silicon-and-germanium-containing material. As previously discussed, the halogen-containing precursor or halogen radicals, if formed, may preferentially react with germanium due to the weaker bond and, thus, the silicon-and-germanium-containing material may be etched selectively over the silicon-containing material. When the precursors include WF₆ and O₂, for example, the WF₆ and O₂ may react to produce F₂. While F₂ may also preferentially react with germanium due to the weaker bond and, thus, the silicon-and-germanium-containing material may be etched selectively over the silicon-containing material, O₂ may oxidize the silicon-and-germanium-containing material and reduce the etch rate of silicon-and-germanium-containing material to a point in which the silicon-containing material is etched at a faster rate than the silicon-and-germanium-containing material. Alternatively, including a boron-containing precursor, whether in the pre-treatment at optional operation 610 or at operation 620, boron may dope the silicon-and-germanium-containing material, as previously discussed, through an electron-donor-acceptor mechanism. As such, the etch rate of silicon-and-germanium-containing material may reduce, causing better etch selectivity toward silicon-containing material relative to silicon-and-germanium-containing material.

Method 600 may include selectively removing at least a portion of the silicon-containing material from the substrate at operation 630. In embodiments, method 600 may remove silicon-containing material without the formation of residue. That is, method 600 may be residue-free. By performing the operations previously discussed, silicon-containing material may be removed relative to silicon-and-germanium-containing material at a selectivity of greater than or about 1:1, and removed at a selectivity of greater than or about 1.1:1, greater than or about 1.2:1, greater than or about 1.3:1, greater than or about 1.4:1, greater than or about 1.5:1, greater than or about 1.6:1, greater than or about 1.7:1, greater than or about 1.8:1, greater than or about 1.9:1, greater than or about 2:1, or more.

While method 600 may selectively remove silicon-containing material relative to silicon-and-germanium-containing material, it is also contemplated that method 600 may remove silicon-containing material relative to silicon-and-oxygen-containing material, such as silicon oxide, silicon-nitrogen-containing material, such as silicon nitride, and various high dielectric constant materials.

An etch rate of the silicon-containing material may be greater than or about 0.5 Å/minute, and may be greater than or about 0.6 Å/minute, greater than or about 0.7 Å/minute, greater than or about 0.75 Å/minute, greater than or about 0.8 Å/minute, greater than or about 0.85 Å/minute, greater than or about 0.9 Å/minute, greater than or about 0.95 Å/minute, greater than or about 1.0 Å/minute, greater than or about 1.05 Å/minute, greater than or about 1.0 Å/minute, greater than or about 1.05 Å/minute, greater than or about 1.1 Å/minute, greater than or about 1.15 Å/minute, greater than or about 1.2 Å/minute, greater than or about 1.25 Å/minute, or more.

Turning to FIGS. 7A-5B, cross-sectional views of structure 700 being processed according to some embodiments of the present technology are illustrated. As illustrated in FIG. 7A substrate 705 may have a plurality of stacked layers overlying the substrate, which may include a layer of a silicon-containing material 710 and a layer of a silicon-and-germanium-containing material 715. As previously discussed, the layer of the silicon-containing material 710 may be, for example, polysilicon and the layer of the silicon-and-germanium-containing material 710 may be, for example, silicon germanium. Although illustrated with only two layers of material, exemplary structures may include any number of layers, and it is to be understood that the figures are only schematics to illustrate aspects of the present technology.

FIG. 7B illustrates the structure after methods according to the present technology have begun to be performed, such as discussed with respect to FIG. 6 above. Precursors or, if formed, plasma effluents may interact with the substrate 705 and exposed materials. As described above, at least a portion of the silicon-containing material 710 may be selectively removed relative to the silicon-and-germanium-containing material 715. By utilizing precursors and processing as discussed throughout the present technology, the silicon-and-germanium-containing material may be etched from the substrate 705.

Process conditions may also impact the operations performed in methods 400 and 600. Each of the operations of methods 400 and 600 may be performed during a constant temperature in embodiments, while in some embodiments the temperature may be adjusted during different operations. Temperatures may be maintained in any range, however, at higher temperatures, etch rates may be increased which may result in higher throughput during processing. Accordingly, in some embodiments the temperature may be maintained at greater than or about 100° C., and may be maintained at greater than or about 125° C., greater than or about 150° C., greater than or about 175° C., greater than or about 200° C., greater than or about 225° C., greater than or about 250° C., greater than or about 275° C., greater than or about 300° C., greater than or about 325° C., greater than or about 350° C., greater than or about 375° C., greater than or about 400° C., greater than or about 425° C., greater than or about 450° C., greater than or about 475° C., greater than or about 500° C., or more.

In embodiments, the process may occur at a variety of pressures, which may facilitate operations in any of a number of process chambers. For example, the process may be performed within chambers capable of providing pressures greater than or about 1 Torr, such as greater than or about 2 Torr, greater than or about 3 Torr, greater than or about 4 Torr, greater than or about 5 Torr, greater than or about 6 Torr, greater than or about 7 Torr, greater than or about 8 Torr, greater than or about 9 Torr, greater than or about 10 Torr, greater than or about 20 Torr, greater than or about 30 Torr, greater than or about 40 Torr, greater than or about 50 Torr, greater than or about 60 Torr, greater than or about 70 Torr, greater than or about 80 Torr, greater than or about 90 Torr, greater than or about 100 Torr, or more. Similar to temperature, at higher pressures, etch rates may be increased which may result in higher throughput during processing.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a fluorine-containing precursor and a secondary precursor to a processing region of a semiconductor processing chamber, wherein the secondary precursor comprises a carbon-containing precursor, a hydrogen-containing precursor, a nitrogen-containing precursor, or an oxygen-containing precursor, wherein a substrate is housed within the processing region, and wherein a silicon-containing material and a silicon-and-germanium-containing material are disposed on the substrate;
contacting the substrate with the fluorine-containing precursor and the secondary precursor; and
selectively removing at least a portion of the silicon-and-germanium-containing material from the substrate, wherein the processing region is maintained at a temperature of greater than or about 200° C.

2. The semiconductor processing method of claim 1, wherein the fluorine-containing precursor comprises nitrogen trifluoride (NF₃), sulfur tetrafluoride (SF₄), sulfur hexafluoride (SF₆), carbon tetrafluoride (CF₄), or tungsten hexafluoride (WF₆).

3. The semiconductor processing method of claim 1, wherein:
the secondary gas is the carbon-containing precursor; and
the carbon containing precursor comprises methane (CH₄).

4. The semiconductor processing method of claim 1, wherein:
the secondary gas is the hydrogen-containing precursor; and
the hydrogen containing precursor comprises diatomic hydrogen (H₂) or ammonia (NH₃).

5. The semiconductor processing method of claim 4, wherein a flow rate ratio of the fluorine-containing precursor relative to the hydrogen-containing precursor is greater than or about 10:1.

6. The semiconductor processing method of claim 1, wherein:
the secondary gas is the nitrogen-containing precursor; and
the nitrogen containing precursor comprises ammonia (NH₃).

7. The semiconductor processing method of claim 1, wherein:
the secondary gas is the oxygen-containing precursor; and
the oxygen containing precursor comprises diatomic oxygen (O₂).

8. The semiconductor processing method of claim 1, wherein the processing region is maintained plasma-free.

9. The semiconductor processing method of claim 1, wherein the processing region is maintained at a pressure of greater than or about 1 Torr.

10. The semiconductor processing method of claim 1, wherein an etch rate of the silicon-and-germanium-containing material is greater than or about 0.5 Å/minute.

11. A semiconductor processing method comprising:
providing a fluorine-containing precursor, an oxygen-containing precursor, and a hydrogen-containing precursor to a processing region of a semiconductor processing chamber, wherein a substrate is housed within the processing region, and wherein a silicon-containing material and a silicon-and-germanium-containing material are disposed on the substrate;
contacting the substrate with the fluorine-containing precursor, the oxygen-containing precursor, and the hydrogen-containing precursor; and
selectively removing at least a portion of the silicon-and-germanium-containing material from the substrate, wherein the processing region is maintained at a temperature of greater than or about 200° C.

12. The semiconductor processing method of claim 11, wherein the fluorine-containing precursor comprises tungsten hexafluoride (WF₆).

13. The semiconductor processing method of claim 11, wherein the oxygen-containing precursor comprises diatomic oxygen (O₂).

14. The semiconductor processing method of claim 11, wherein the hydrogen-containing precursor comprises diatomic hydrogen (H₂).

15. The semiconductor processing method of claim 11, wherein the processing region is maintained plasma-free.

16. The semiconductor processing method of claim 11, wherein the processing region is maintained at a temperature of greater than or about 400° C.

17. The semiconductor processing method of claim 11, wherein the processing region is maintained at a pressure of greater than or about 3 Torr.

18. A semiconductor processing method comprising:
providing a halogen-containing precursor and one or more secondary precursors to a processing region of a semiconductor processing chamber, wherein the secondary precursors comprise a carbon-containing precursor, a hydrogen-containing precursor, a nitrogen-containing precursor, or an oxygen-containing precursor, wherein a substrate is housed within the processing region, and wherein a silicon-containing material and a silicon-and-germanium-containing material are disposed on the substrate;
contacting the substrate with the halogen-containing precursor and the secondary precursor; and
selectively removing at least a portion of the silicon-and-germanium-containing material from the substrate, wherein the processing region is maintained plasma-free.

19. The semiconductor processing method of claim 18, wherein the halogen-containing precursor comprises nitrogen trifluoride (NF₃), sulfur tetrafluoride (SF₄), sulfur hexafluoride (SF₆), carbon tetrafluoride (CF₄), or tungsten hexafluoride (WF₆).

20. The semiconductor processing method of claim 18, wherein the processing region is maintained at a temperature of greater than or about 350° C.
